(19) United States
(12) Patent Application Publication
(10) Pub. No.: US 2019/0363070 A1
(43) Pub. Date: Nov. 28, 2019

(54) LIGHT EMITTING DIODE SURFACE LIGHTING SOURCE, AND MANUFACTURING METHOD AND DISPLAY PANEL THEREOF

(71) Applicant: Wuhan China Star Optoelectronics Technology Co., Ltd., Wuhan (CN)

(72) Inventors: Guiyang ZHANG, Wuhan (CN); Guowei ZHA, Wuhan (CN); Hongqing CUI, Wuhan (CN)

(21) Appl. No.: 16/152,705

(22) Filed: Oct. 5, 2018

Related U.S. Application Data
(63) Continuation of application No. PCT/CN2018/095691, filed on Jul. 13, 2018.

(30) Foreign Application Priority Data
May 28, 2018 (CN) 201810520814.6

(51) Int. Cl. H01L 25/075; H01L 33/60; H01L 33/62; H01L 33/50; H01L 33/58

(52) U.S. Cl. CPC H01L 25/0753; H01L 33/60; H01L 33/62; H01L 33/505; H01L 25/167; H01L 2933/0058; H01L 2933/0066; H01L 2933/0041; H01L 33/58

(57) ABSTRACT

Provided are a LED surface lighting source, and a manufacturing method and a display panel thereof. The method comprises: forming a highly reflective dielectric film on a driving substrate, wherein the highly reflective dielectric film comprises two transparent organic films and a highly reflective metal film sandwiched inbetween, and the highly reflective metal film is a metal film having a reflective rate greater than 90%; etching vias arranged in array on the highly reflective dielectric film; forming an organic insulating film in the vias and curing the organic insulating film, or coating an organic insulating film on lateral sides of LEDs and curing the organic insulating film; positioning the LEDs in the vias, and fixing the LEDs on the driving substrate, wherein the LEDs are electrically connected to the driving substrate, and the LEDs are insulated from the highly reflective metal film by the organic insulating film.

### CROSS-REFERENCE TO RELATED APPLICATION

This application is a continuing application of PCT Patent Application No. PCT/CN2018/095691 entitled “Light emitting diode surface lighting source, and manufacturing method and display panel thereof”, filed on Jul. 13, 2018, which claims priority to Chinese Patent Application No. 201810520814.6, filed on May 28, 2018, both of which are hereby incorporated in its entireties by reference.

### FIELD OF THE INVENTION

The present invention relates to a light emitting diode (LED) field, and more particularly to a light emitting diode surface lighting source, and a manufacturing method and a display panel thereof.

### BACKGROUND OF THE INVENTION

After decades of development, the display industry has seen the era of CRT (Cathode Ray Tube), PDP (Plasma Display Panel) and LCD (Liquid Crystal Display). The only remaining LCD display technology has undergone a series of updates, and has formed a display technology based on LTPS (Low Temperature Poly-Silicon), which is widely used in television, mobile phones and automotive applications.

In recent years, the self-luminous OLED (Organic Light Emitting Display) has gradually emerged in the display market, and has been favored by consumers because of high color gamut, fast response, high contrast, flexible foldability and low power consumption. However, the OLED luminescent materials will be affected by factors such as water, oxygen and high temperature in the air, so it will be inferior to LTPS LCD in terms of life and reliability. For getting rid of the fate of being rejected by the market, LCD manufacturers are committed to developing a new display technology with a better display performance than OLED, thus micro-LED (micro LED) display emerges as the times require. The micro-LEDs of three colors of RGB (red, green and blue) are used as sub-pixels of the display, and a switch of each sub-pixel is controlled by a driving TFT (Thin Film Transistor) (as shown in FIG. 1). In FIG. 1, 1′ is a driving substrate, and 2′ is a paint reflective layer, and 3′ is a transparent protective layer, and 4′ is a uniform film, and 5′ is a brightness enhancement film, and 6′ is a micro-LED.

Compared with the OLED materials, the inorganic LED materials have higher luminous efficiency. More importantly, the inorganic LED materials are not affected by water vapor, oxygen or high temperature, so the inorganic LED materials have obvious advantages in terms of stability, service life and operating temperature. Secondly, as a display screen for mobile phones, wearable devices and VR/AR devices, the LED display consumes less power and utilizes long-term battery life with a lower cost.

Although micro-LED display technology takes into account the common advantages of LCD display and OLED display, so far such technology is still in the laboratory research stage, and the current technology can not accomplish this ambitious goal. Therefore, a compromise method is created. A mini-LED (mini-LED) blue chip with a geometric size of several hundred micrometers is used with a yellow fluorescent film (as shown in FIG. 2) or a quantum dot film to fabricate a novel LED direct-type backlight structure to cooperate with a liquid crystal panel for display. In FIG. 2, 1′ is a drive substrate, and 2′ is a paint reflective layer, and 5′ is a brightness enhancement film, and 7′ is a fluorescent film, and 8′ is a diffusion film, and 9′ is a mini-LED. Generally, a FPC (Flexible Printed Circuit) or a PCB (Printed Circuit Board) is used as a base layer, and an LED driving circuit is disposed thereon. In order to avoid short circuit and improve the light effect of the LED surface lighting source, a paint reflective layer having a thickness of dozens of micrometers is generally applied between the LEDs and the circuit. Generally, the reflection rate of this paint layer is about 80%, which is difficult to meet the current light effect requirements of mini-LED.

### SUMMARY OF THE INVENTION

For solving the aforesaid technical issues, the present invention provides a light emitting diode surface lighting source, and a manufacturing method and a display panel thereof, which can improve the lighting effect of the LED surface lighting source, and reduce the thickness of the LED surface lighting source.

The manufacturing method of the light emitting diode surface lighting source provided by the present invention comprises:

forming a highly reflective dielectric film on a driving substrate, wherein the highly reflective dielectric film comprises two transparent organic films and a highly reflective metal film sandwiched between the two transparent organic films, and the highly reflective metal film is a metal film having a reflective rate greater than 90%;

etching a plurality of vias arranged in an array on the highly reflective dielectric film;

forming an organic insulating film in the plurality of vias and curing the organic insulating film in the plurality of vias, or coating an organic insulating film on lateral sides of a plurality of light emitting diodes and curing the organic insulating film on the lateral sides of the plurality of light emitting diodes;

positioning the plurality of light emitting diodes in the plurality of vias, and fixing the plurality of light emitting diodes on the driving substrate, wherein the plurality of light emitting diodes is electrically connected to the driving substrate, and the light emitting diodes are insulated from the highly reflective metal film by the organic insulating film.

Preferably, the manufacturing method further comprises a step of:

forming a light emitting layer on the highly reflective dielectric film to cover the plurality of light emitting diodes; wherein the light emitting layer is one of a fluorescent film, a quantum dot film and a ceramic fluorescent film;

forming a diffusion film on the light emitting layer;

forming a brightness enhancement film on the diffusion film.

Preferably, a thickness range of the two transparent organic films is 0.5 to 3 micrometers, and a thickness of the highly reflective metal film does not exceed 1 micrometer.

Preferably, a shape of the vias on the highly reflective dielectric film matches a shape of the light emitting diodes.

Preferably, the manufacturing method further comprises a step of:

aligning a plurality of meshes on a steel mesh with the plurality of vias on the highly reflective dielectric film, and injecting a conductive adhesive layer into the plurality of vias through the plurality of meshes, and positioning the plurality of light emitting diodes respectively above the conductive adhesive layer in the plurality of vias;

wherein fixing the plurality of light emitting diodes on the driving substrate, comprises:

fixing the plurality of light emitting diodes on the driving substrate by reflow soldering after positioning the plurality of light emitting diodes respectively above the conductive adhesive layer in the plurality of vias.

Preferably, the plurality of vias arranged in an array is etched on the highly reflective dielectric film by ion beam etching or electron beam etching.

Preferably, the highly reflective metal film is made of one of metallic silver, metallic aluminum and metallic ruthenium;

the transparent organic films and the organic insulating film are made of one of a polyimide material, a poly 1,4-cyclohexylene dimethylene terephthalate material, a polyethylene terephthalate material and an epoxy resin material.

The present invention further provides a light emitting diode surface lighting source, comprising a driving substrate, a highly reflective dielectric film on the driving substrate and a plurality of light emitting diodes;

wherein the highly reflective dielectric film comprises two transparent organic films and a highly reflective metal film sandwiched between the two transparent organic films, and the highly reflective metal film is a metal film having a reflective rate greater than 90%;

wherein a plurality of vias arranged in an array is etched on the highly reflective dielectric film, and an organic insulating film is formed in the plurality of vias or an organic insulating film is coated on lateral sides of a plurality of light emitting diodes;

the plurality of light emitting diodes are respectively positioned in the plurality of vias and insulated from the highly reflective metal film by the organic insulating film, and the plurality of light emitting diodes is fixed on the driving substrate, and the plurality of light emitting diodes is electrically connected to the driving substrate.

Preferably, the light emitting diode surface lighting source further comprises a light emitting layer, a diffusion film and a brightness enhancement film, which are sequentially stacked, wherein the light emitting layer covers the plurality of light emitting diodes; the light emitting layer is one of a fluorescent film, a quantum dot film and a ceramic fluorescent film;

the highly reflective metal film is made of one of metallic silver, metallic aluminum and metallic ruthenium;

the transparent organic films and the organic insulating film are made of one of a polyimide material, a poly 1,4-cyclohexylene dimethylene terephthalate material, a polyethylene terephthalate material and an epoxy resin material;

the driving substrate comprises a plurality of driving circuits, and the plurality of light emitting diodes are divided into a plurality of light emitting diode regions, and each light emitting diode region corresponds to at least one light emitting diode;

wherein each drive circuit is used to drive a light emitting diode in one light emitting diode region.

The present invention further provides a display panel, comprising a light emitting diode surface lighting source, wherein the light emitting diode surface lighting source comprises a driving substrate, a highly reflective dielectric film on the driving substrate and a plurality of light emitting diodes;

wherein the highly reflective dielectric film comprises two transparent organic films and a highly reflective metal film sandwiched between the two transparent organic films, and the highly reflective metal film is a metal film having a reflective rate greater than 90%;

wherein a plurality of vias arranged in an array is etched on the highly reflective dielectric film, and an organic insulating film is formed in the plurality of vias or an organic insulating film is coated on lateral sides of a plurality of light emitting diodes;

the plurality of light emitting diodes are respectively positioned in the plurality of vias and insulated from the highly reflective metal film by the organic insulating film, and the plurality of light emitting diodes is fixed on the driving substrate, and the plurality of light emitting diodes is electrically connected to the driving substrate.

Preferably, the light emitting diode surface lighting source further comprises a light emitting layer, a diffusion film and a brightness enhancement film, which are sequentially stacked, wherein the light emitting layer covers the plurality of light emitting diodes; the light emitting layer is one of a fluorescent film, a quantum dot film and a ceramic fluorescent film;

the highly reflective metal film is made of one of metallic silver, metallic aluminum and metallic ruthenium;

the transparent organic films and the organic insulating film are made of one of a polyimide material, a poly 1,4-cyclohexylene dimethylene terephthalate material, a polyethylene terephthalate material and an epoxy resin material.

Preferably, the driving substrate comprises a plurality of driving circuits, and the plurality of light emitting diodes are divided into a plurality of light emitting diode regions, and each light emitting diode region corresponds to at least one light emitting diode;

wherein each drive circuit is used to drive a light emitting diode in one light emitting diode region.

The implementation of the present invention possesses the following results: the paint reflective layer in the prior art is replaced with the highly reflective dielectric film in the present invention. The highly reflective dielectric film comprises the highly reflective metal film, which can significantly improve the reflectance of the highly reflective dielectric film, i.e., to improve the light effect of the LED surface lighting source. Meanwhile, the highly reflective metal film is a metal film. Compared with the paint reflective layer, the thickness can be decreased, thereby to reduce the overall thickness of the LED surface lighting source.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a schematic structure diagram of a micro-LED surface lighting source according to the prior art.

FIG. 2 is a schematic structure diagram of a mini-LED surface lighting source according to the prior art.

FIG. 3 is a flowchart of a manufacturing method of an LED surface lighting source according to the present invention.

FIG. 4 is a schematic structure diagram of an LED surface lighting source according to the present invention.

FIG. 5 is a schematic structure diagram of a highly reflective dielectric layer according to the present invention.

FIG. 6 is a schematic diagram of vias etched on a highly reflective dielectric layer according to the present invention.

FIG. 7 is a schematic diagram of a conductive adhesive layer injected into meshes of a steel mesh according to the present invention.

FIG. 8 is a schematic diagram of LEDs of the present invention positioned in vias of a highly reflective dielectric layer.

FIG. 9 is a schematic structure diagram of a liquid crystal display panel according to the present invention.

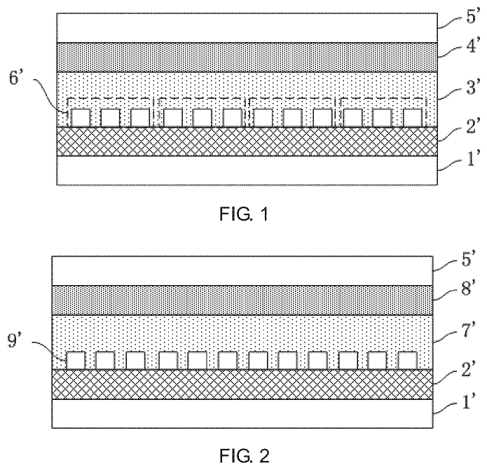

### DETAILED DESCRIPTION OF PREFERRED EMBODIMENTS

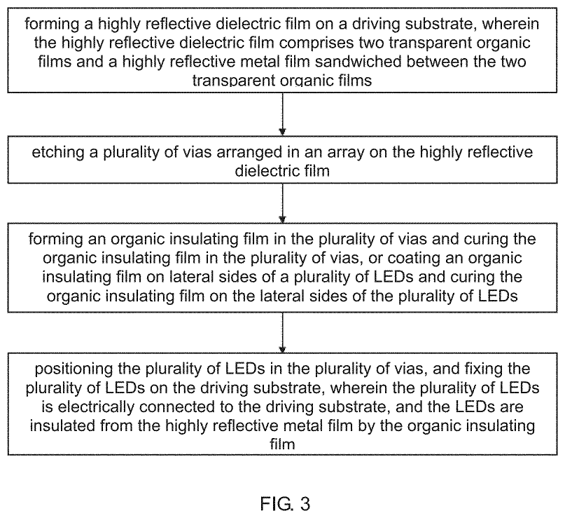

The invention provides a manufacturing method of an LED (Light Emitting Diode) surface lighting source 10. As shown in FIG. 3, the manufacturing method comprises the following steps:

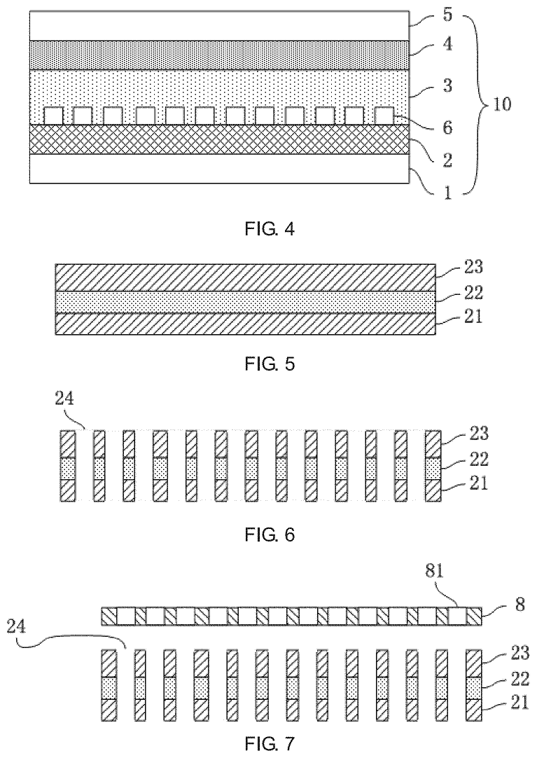

as shown in FIG. 4, forming a highly reflective dielectric film 2 on a driving substrate 1, wherein as shown in FIG. 5, the highly reflective dielectric film 2 comprises two transparent organic films 21, 23 and a highly reflective metal film 22 sandwiched between the two transparent organic films 21, 23, and the highly reflective metal film 22 is a metal film having a reflective rate greater than 90%; the highly reflective metal film 22 is made of one of metallic silver, metallic aluminum and metallic ruthenium. The two transparent organic films 21, 23 in the highly reflective dielectric film 2 are heat-resistant transparent organic films. A drive circuit for driving the LED to emit light is disposed on the driving substrate 1.

As shown in FIG. 6, etching a plurality of vias 24 arranged in an array on the highly reflective dielectric film 2; a shape of the vias 24 on the highly reflective dielectric film 2 matches a shape of the LEDs 6, such as a square via, a circular via or a via of other shapes; the plurality of vias 24 arranged in an array is etched on the highly reflective dielectric film 2 by a high precision etching process, such as ion beam etching or electron beam etching.

An organic insulating film is formed in the plurality of vias 24 and the organic insulating film in the plurality of vias 24 is cured, or an organic insulating film is coated on lateral sides of a plurality of LEDs 6 and the organic insulating film on the lateral sides of the plurality of LEDs 6 is cured.

As shown in FIG. 7, a plurality of meshes 81 on a steel mesh 8 is aligned with the plurality of vias 24 on the highly reflective dielectric film 2, and a conductive adhesive layer is injected into the plurality of vias 24 through the plurality of meshes 81. Within 5 to 20 minutes after injecting the conductive adhesive layer into the plurality of vias 24, the plurality of LEDs 6 is respectively positioned above the conductive adhesive layer in the plurality of vias 24, such that the LEDs 6 are in contact with the conductive adhesive layer. The conductive adhesive layer here may be a solder paste or other easily cooled and solidified metal. The height uniformity of the conductive adhesive layer in various vias 24 of the highly reflective dielectric film 2 can be precisely controlled by controlling the concentration and content of the conductive adhesive layer and the duration of injecting the conductive adhesive layer. Namely, the heights of the conductive adhesive layers in the vias 24 on the highly reflective dielectric film 2 are all the same, so that uniformity of illumination of the plurality of LEDs 6 can be ensured.

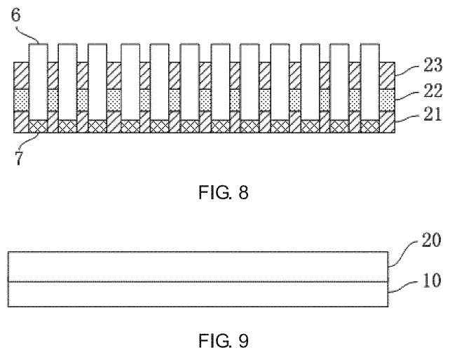

As shown in FIG. 8, the plurality of LEDs 6 is respectively positioned in the plurality of vias 24 by transferring, and the plurality of LEDs 6 is fixed on the driving substrate 1 by the conductive adhesive layer 7. The plurality of LEDs 6 and the driving substrate 1 are electrically connected with the conductive adhesive layer 7, and the LEDs 6 are insulated from the highly reflective metal film 22 by the organic insulating films to avoid the short-circuiting between the highly reflective metal film 22 and the metal on the surface of the LEDs 6.

In the present invention, by replacing the paint reflective layer in the prior art with the highly reflective metal film 22, not only the reflection effect of the light can be improved, but also more light is emitted from the surface of the surface lighting source, which greatly improves the brightness of the LED surface lighting source 10. Meanwhile, the highly reflective metal film 22 can also be made very thin, generally no more than 1 micrometer, and the thickness of the LED surface lighting source 10 can be reduced relative to the thickness of the paint reflective layer with dozens of micrometers.

Forming a highly reflective dielectric film 2 on a driving substrate 1 specifically comprises:

forming a first transparent organic film 21 on the driving substrate 1, and drying and curing the first transparent organic film 21;

preparing a highly reflective metal film 22 on the first transparent organic film 21 by sputtering or evaporation;

forming a second transparent organic film 23 on the highly reflective metal film 22, and drying and curing the second transparent organic film 23.

The first transparent organic film 21 can insulate and separate the highly reflective metal film from the circuit on the driving substrate 1 and can be used as a buffer later between the driving substrate 1 and LEDs 6. The first transparent organic film 21 and the second transparent organic film 23 can insulate the LEDs 6 from water and oxygen in the air.

The aforesaid transparent organic films and the organic insulating film are made of one of a polyimide (PI) material, a poly 1,4-cyclohexylene dimethylene terephthalate (PCT) material, a polyethylene terephthalate (PET) material and an epoxy resin material.

The manufacturing method of the light emitting diode surface lighting source 10 further comprises:

forming a light emitting layer 3 on the highly reflective dielectric film 2 to cover the plurality of light emitting diodes 6; wherein the light emitting layer 3 is one of a fluorescent film, a quantum dot film and a ceramic fluorescent film;

forming a diffusion film 4 on the light emitting layer 3;

forming a brightness enhancement film 5 on the diffusion film 4.

Preferably, a thickness range of the two transparent organic films is 0.5 to 3 micrometers, and a thickness of the highly reflective metal film 22 does not exceed 1 micrometer.

Fixing the plurality of LEDs 6 on the driving substrate 1 specifically comprises:

fixing the plurality of LEDs 6 on the driving substrate 1 by reflow soldering after positioning the plurality of LEDs 6 respectively above the conductive adhesive layer in the plurality of vias 24. Namely, after the conductive adhesive layer is heated and melted, it is cured. The LEDs 6 are fixed on the driving substrate 1 by the cured conductive adhesive layer so that the LEDs 6 are tightly bonded to the driving substrate 1 and the highly reflective dielectric layer at the bottom of the conductive adhesive layer.

After the preparation of the highly reflective dielectric film 2 is accomplished, the subsequent LEDs 6 are mounted and the light emitting layer 3 and the associated optical films (diffusion film 4, brightness enhancement film 5) are prepared to form a direct-type backlight source.

The present invention further provides a LED surface lighting source 10, as shown in FIG. 4, comprising; a driving substrate 1, a highly reflective dielectric film 2 on the driving substrate 1 and a plurality of LEDs 6.

As shown in FIG. 5, the highly reflective dielectric film 2 comprises two transparent organic films 21, 23 and a highly reflective metal film 22 sandwiched between the two transparent organic films 21, 23, and the highly reflective metal film 22 is a metal film having a reflective rate greater than 90%.

As shown in FIG. 6, a plurality of vias 24 arranged in an array is etched on the highly reflective dielectric film 2, and an organic insulating film is formed in the plurality of vias 24 or an organic insulating film is coated on lateral sides of a plurality of LEDs 6.

As shown in FIG. 8, the plurality of LEDs 6 are respectively positioned in the plurality of vias 24 and insulated from the highly reflective metal film 22 by the organic insulating film, and the plurality of LEDs 6 is fixed on the driving substrate 1, and the plurality of LEDs 6 is electrically connected to the driving substrate 1.

The LED surface lighting source 10 further comprises a light emitting layer 3, a diffusion film 4 and a brightness enhancement film 5, which are sequentially stacked, wherein the light emitting layer 3 covers the plurality of LEDs 6; the light emitting layer 3 is one of a fluorescent film, a quantum dot film and a ceramic fluorescent film.

The aforesaid highly reflective metal film 22 is made of one of metallic silver, metallic aluminum and metallic ruthenium; the transparent organic films and the organic insulating film are made of one of a polyimide material, a poly 1,4-cyclohexylene dimethylene terephthalate material, a polyethylene terephthalate material and an epoxy resin material.

The driving substrate 1 comprises a plurality of driving circuits, and the plurality of light emitting diodes 6 are divided into a plurality of light emitting diode regions, and each light emitting diode region corresponds to at least one light emitting diode 6; wherein each drive circuit is used to drive a light emitting diode 6 in one light emitting diode region.

The present invention further provides a display panel. The display panel may be a liquid crystal display panel or a micro LED display panel. Certainly, the type of the display panel is not limited thereto. In this embodiment, the liquid crystal display panel is illustrated for explanation. As shown in FIG. 9, the liquid crystal display panel comprises the aforesaid LED surface lighting source 10 and a liquid crystal cell 20 on the LED surface lighting source 10. The liquid crystal cell 20 comprises an upper polarizer, a lower polarizer and a liquid crystal sandwiched between the two polarizers.

Specifically, the LED surface lighting source 10 is controlled in local regions. The driving substrate 1 includes a PCB (Printed Circuit Board) or an FPC (Flexible Printed Circuit) board. A plurality of driving circuits is prepared on the PCB or the FPC board. The plurality of LEDs 6 on the entire surface are divided into m×n LED regions, and both m and n are positive integers greater than or equal to 1. The more the number of LED regions is, the finer the control of the LED surface lighting source will be, and the better the detailed processing of the display screen can be achieved. The region-controlled LED surface lighting source is equipped with local dimming technology to improve the contrast of the display while saving power consumption. For instance, as one LED region is required for display, the other LED regions may not light up. Thus, the power consumption can be saved, and meanwhile the current for controlling the other LED regions can be transmitted to the one LED region, which needs to be illuminated. Then, the brightness of this LED region will be higher to improve the contrast of the display image.

In conclusion, the paint reflective layer in the prior art is replaced with the highly reflective dielectric film 2 in the present invention. The highly reflective dielectric film 2 comprises the highly reflective metal film 22, which can significantly improve the reflectance of the highly reflective dielectric film 2, i.e., to improve the light effect of the LED surface lighting source 10. Meanwhile, the highly reflective metal film 22 is a metal film. Compared with the paint reflective layer, the thickness can be decreased, thereby to reduce the overall thickness of the LED surface lighting source.

The above content with the specific preferred embodiments of the present invention is further made to the detailed description, the specific embodiments of the present invention should not be considered limited to these descriptions. Those of ordinary skill in the art for the present invention, without departing from the spirit of the present invention, can make various simple deduction or replacement, should be deemed to belong to the scope of the present invention.

What is claimed is:

1. A manufacturing method of a light emitting diode surface lighting source, comprising:
forming a highly reflective dielectric film on a driving substrate, wherein the highly reflective dielectric film comprises two transparent organic films and a highly reflective metal film sandwiched between the two transparent organic films, and the highly reflective metal film is a metal film having a reflective rate greater than 90%;
etching a plurality of vias arranged in an array on the highly reflective dielectric film;
forming an organic insulating film in the plurality of vias and curing the organic insulating film in the plurality of vias, or coating an organic insulating film on lateral sides of a plurality of light emitting diodes and curing the organic insulating film on the lateral sides of the plurality of light emitting diodes;
positioning the plurality of light emitting diodes in the plurality of vias, and fixing the plurality of light emitting diodes on the driving substrate, wherein the plurality of light emitting diodes is electrically connected to the driving substrate, and the light emitting diodes are insulated from the highly reflective metal film by the organic insulating film.

2. The manufacturing method of the light emitting diode surface lighting source according to claim 1, further comprising:
forming a light emitting layer on the highly reflective dielectric film to cover the plurality of light emitting diodes; wherein the light emitting layer is one of a fluorescent film, a quantum dot film and a ceramic fluorescent film;
forming a diffusion film on the light emitting layer;
forming a brightness enhancement film on the diffusion film.

3. The manufacturing method of the light emitting diode surface lighting source according to claim 1, wherein a thickness range of the two transparent organic films is 0.5 to 3 micrometers, and a thickness of the highly reflective metal film does not exceed 1 micrometer.

4. The manufacturing method of the light emitting diode surface lighting source according to claim 1, wherein a shape of the vias on the highly reflective dielectric film matches a shape of the light emitting diodes.

5. The manufacturing method of the light emitting diode surface lighting source according to claim 1, further comprising:
aligning a plurality of meshes on a steel mesh with the plurality of vias on the highly reflective dielectric film, and injecting a conductive adhesive layer into the plurality of vias through the plurality of meshes, and positioning the plurality of light emitting diodes respectively above the conductive adhesive layer in the plurality of vias;
wherein fixing the plurality of light emitting diodes on the driving substrate, comprises:
fixing the plurality of light emitting diodes on the driving substrate by reflow soldering after positioning the plurality of light emitting diodes respectively above the conductive adhesive layer in the plurality of vias.

6. The manufacturing method of the light emitting diode surface lighting source according to claim 1, wherein the plurality of vias arranged in an array is etched on the highly reflective dielectric film by ion beam etching or electron beam etching.

7. The manufacturing method of the light emitting diode surface lighting source according to claim 1, wherein
the highly reflective metal film is made of one of metallic silver, metallic aluminum and metallic ruthenium;
the transparent organic films and the organic insulating film are made of one of a polyimide material, a poly 1,4-cyclohexylene dimethylene terephthalate material, a polyethylene terephthalate material and an epoxy resin material.

8. A light emitting diode surface lighting source, comprising a driving substrate, a highly reflective dielectric film on the driving substrate and a plurality of light emitting diodes;
wherein the highly reflective dielectric film comprises two transparent organic films and a highly reflective metal film sandwiched between the two transparent organic films, and the highly reflective metal film is a metal film having a reflective rate greater than 90%;
wherein a plurality of vias arranged in an array is etched on the highly reflective dielectric film, and an organic insulating film is formed in the plurality of vias or an organic insulating film is coated on lateral sides of a plurality of light emitting diodes;
the plurality of light emitting diodes are respectively positioned in the plurality of vias and insulated from the highly reflective metal film by the organic insulating film, and the plurality of light emitting diodes is fixed on the driving substrate, and the plurality of light emitting diodes is electrically connected to the driving substrate.

9. The light emitting diode surface lighting source according to claim 8, further comprising a light emitting layer, a diffusion film and a brightness enhancement film, which are sequentially stacked, wherein the light emitting layer covers the plurality of light emitting diodes; the light emitting layer is one of a fluorescent film, a quantum dot film and a ceramic fluorescent film;
the highly reflective metal film is made of one of metallic silver, metallic aluminum and metallic ruthenium;
the transparent organic films and the organic insulating film are made of one of a polyimide material, a poly 1,4-cyclohexylene dimethylene terephthalate material, a polyethylene terephthalate material and an epoxy resin material; the driving substrate comprises a plurality of driving circuits, and the plurality of light emitting diodes are divided into a plurality of light emitting diode regions, and each light emitting diode region corresponds to at least one light emitting diode;
wherein each drive circuit is used to drive a light emitting diode in one light emitting diode region.

10. A display panel, comprising a light emitting diode surface lighting source, wherein the light emitting diode surface lighting source comprises a driving substrate, a highly reflective dielectric film on the driving substrate and a plurality of light emitting diodes;
wherein the highly reflective dielectric film comprises two transparent organic films and a highly reflective metal film sandwiched between the two transparent organic films, and the highly reflective metal film is a metal film having a reflective rate greater than 90%;
wherein a plurality of vias arranged in an array is etched on the highly reflective dielectric film, and an organic insulating film is formed in the plurality of vias or an organic insulating film is coated on lateral sides of a plurality of light emitting diodes;
the plurality of light emitting diodes are respectively positioned in the plurality of vias and insulated from the highly reflective metal film by the organic insulating film, and the plurality of light emitting diodes is fixed on the driving substrate, and the plurality of light emitting diodes is electrically connected to the driving substrate.

11. The display panel according to claim 10, wherein the light emitting diode surface lighting source further comprises a light emitting layer, a diffusion film and a brightness enhancement film, which are sequentially stacked, wherein the light emitting layer covers the plurality of light emitting diodes; the light emitting layer is one of a fluorescent film, a quantum dot film and a ceramic fluorescent film;
the highly reflective metal film is made of one of metallic silver, metallic aluminum and metallic ruthenium;
the transparent organic films and the organic insulating film are made of one of a polyimide material, a poly 1,4-cyclohexylene dimethylene terephthalate material, a polyethylene terephthalate material and an epoxy resin material.

12. The display panel according to claim 10, wherein
the driving substrate comprises a plurality of driving circuits, and the plurality of light emitting diodes are divided into a plurality of light emitting diode regions, and each light emitting diode region corresponds to at least one light emitting diode;
wherein each drive circuit is used to drive a light emitting diode in one light emitting diode region.
